(19) United States
(12) Patent Application Publication
(10) Pub. No.: US 2026/0089852 A1
(43) Pub. Date: Mar. 26, 2026

(54) ELECTRONIC DEVICE AND CASE

(71) Applicant: CASIO COMPUTER CO., LTD., Tokyo (JP)

(72) Inventors: Yuichi NISHIMURA, Tokyo (JP); Masaki OGINO, Tokyo (JP)

(73) Assignee: CASIO COMPUTER CO., LTD., Tokyo (JP)

(21) Appl. No.: 19/332,077

(22) Filed: Sep. 18, 2025

(30) Foreign Application Priority Data
Sep. 24, 2024 (JP) 2024-164708

(51) Int. Cl. H05K 5/02

(52) U.S. Cl. CPC H05K 5/02

(57) ABSTRACT

An electronic device includes a case including a coating layer on a surface of a base material. The coating layer includes a first coating layer that is provided on the base material and a second coating layer that includes a raw lacquer and is provided on the first coating layer. The first coating layer is configured to improve adhesion between the base material and the first coating layer and between the first coating layer and the second coating layer. The second coating layer has a first area and a second area where the second coating layer is thinner than in the first area, and is configured such that a paint color of the first coating layer is visible through the second coating layer in the second area.

### REFERENCE TO RELATED APPLICATIONS

This application is based upon and claims the benefit of priority from the prior Japanese Patent Application No. 2024-164708, filed on Sep. 24, 2024, the entire contents of which are incorporated herein by reference.

### TECHNICAL FIELD

The present disclosure relates to an electronic device and a case.

### DESCRIPTION OF RELATED ART

There is disclosed, for example, in JP 2005-229080 A, a conventional electrical product with a lacquered exterior for decorative purposes.

### SUMMARY OF THE INVENTION

According to an aspect of the present disclosure, there is provided an electronic device including a case including a coating layer on a surface of a base material,
wherein the coating layer includes a first coating layer that is provided on the base material and a second coating layer that includes a raw lacquer and is provided on the first coating layer,
wherein the first coating layer is configured to improve adhesion between the base material and the first coating layer and between the first coating layer and the second coating layer, and
wherein the second coating layer has a first area and a second area where the second coating layer is thinner than in the first area, and is configured such that a paint color of the first coating layer is visible through the second coating layer in the second area.

### BRIEF DESCRIPTION OF DRAWINGS

FIG. 1 is a perspective view showing an overview of a calculator as an example of an electronic device.

FIG. 2 shows a manufacturing process of a case.

FIG. 3A is a sectional view taken along a broken line in FIG. 2 viewed in a direction indicated by arrows A, A.

FIG. 3B shows an example in which the size of an R shape in the sectional view of FIG. 2 is reduced.

FIG. 3C shows a part shown in FIG. 3A viewed from above the top surface of an upper case.

FIG. 3D shows a part shown in FIG. 3B viewed from above the top surface of the upper case.

### DETAILED DESCRIPTION

Hereinafter, one or more embodiments of an electronic device according to the present disclosure will be described with reference to the drawings. In the present disclosure, a calculator is used as an example of the electronic device, but the electronic device is not limited thereto. Examples thereof include an electronic dictionary, a tablet terminal, and a cell phone.

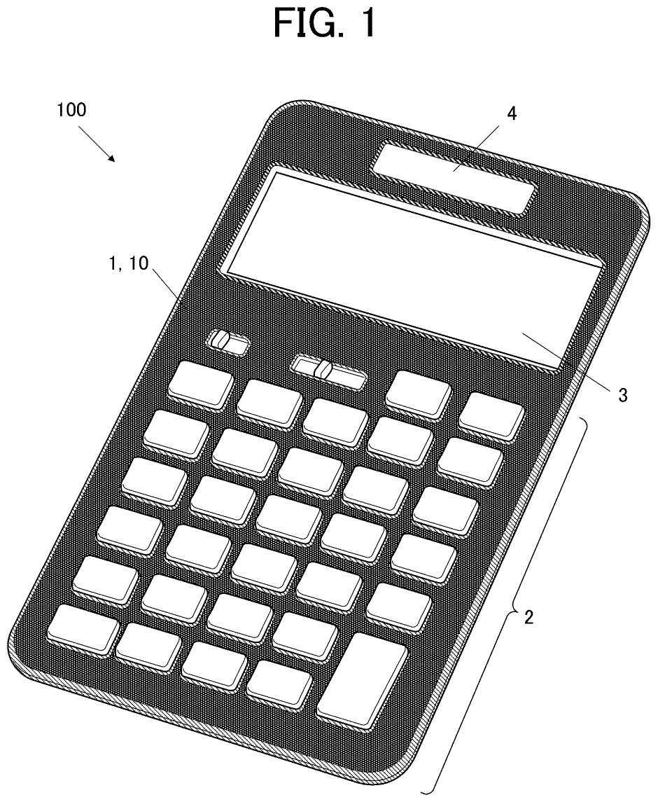

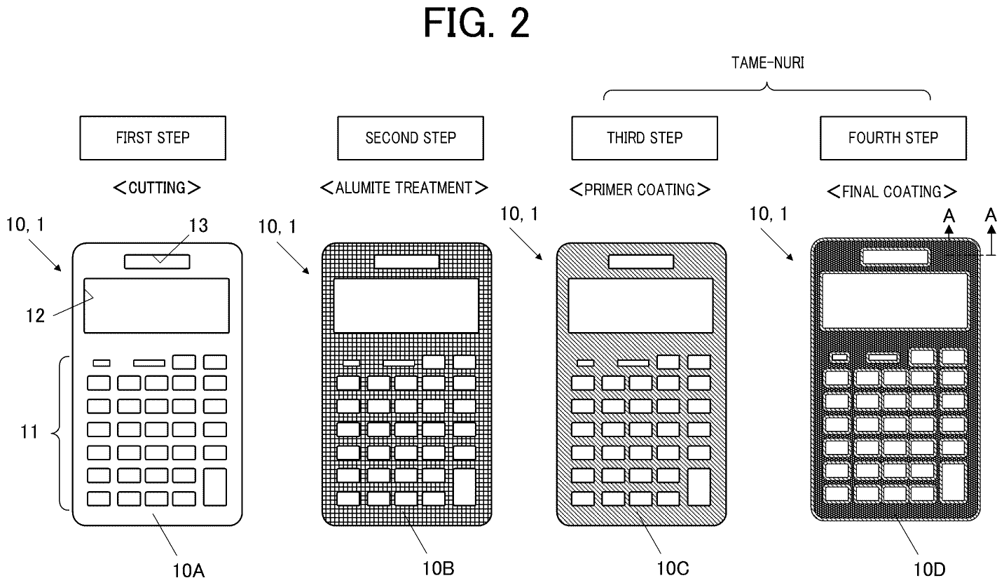

As shown in FIG. 1, a calculator 100 includes a case 1, an input key unit 2 including keys of various key groups, a display 3, and a solar panel 4. The case 1 includes a not-shown lower case that fixes a not-shown circuit board that drives and controls the calculator 100, and an upper case 10 that covers and seals an opening of the lower case. The upper case 10 has openings 11 (shown in FIG. 2) that expose the keys of the input key unit 2. The upper case 10 also has an opening 12 (shown in FIG. 2) that exposes the display 3 and an opening 13 (shown in FIG. 2) that exposes the solar panel 4. Tame-nuri (described later) is performed on the outer surface of the case 1, so that the color (e.g., vermilion) of an underlayer (first coating layer 10C shown in FIG. 2) is visible through shuai urushi (of suki urushi, i.e., transparent lacquer) of a surface layer (second coating layer 10D shown in FIG. 2). Hereinafter, the external appearance in which the color of the underlayer is visible through shuai urushi is referred to as “color tone by tame-nuri”.

The input key unit 2 receives user's input operations of formula components such as numerical values and calculation symbols, and also receives user's instruction operations of various processes. The input key unit 2 includes keys (keys of a numeric keypad, cursor keys, etc.) to which unique functions are assigned. The display 3 is composed of, for example, a liquid crystal display (LCD) and displays, with dots, various data such as characters, signs, and symbols corresponding to the operations on the input key unit 2 or the like. The solar panel 4 has a power generation area that functions as a solar cell that generates electric power by receiving light. The electric power generated by the solar panel 4 is stored in a not-shown secondary battery.

Next, a manufacturing process of the case 1 will be described with reference to FIG. 2. Although FIG. 2 shows the upper case 10 as a representative of the components of the case 1, the not-shown lower case is also manufactured through the same manufacturing process as the upper case 10. The base material of the case 1 is aluminum. As shown in FIG. 2, in the first step, an aluminum base 10A is cut to have the shape of the upper case 10 (case 1). Then, in the second step, an alumite treatment (anodization), to be specific, a color alumite treatment, is performed on the (front/upper) surface of the aluminum base 10A to form an aluminum oxide film 10B thereon. At the time, black dye is used, so that the aluminum oxide film 10B becomes black. This can improve corrosion resistance and abrasion resistance of the upper case 10. In addition, in the below-described third step in which a urethane-based paint is applied, adhesion of the urethane-based paint is stronger when it is applied to the aluminum base 10A on which the alumite treatment has been performed than when it is applied to the aluminum base 10A on which the alumite treatment has not been performed. Further, since the aluminum oxide film 10B is formed on the surface of aluminum base 10A, and black dye is used to make the surface black, the color (silvery white) of the aluminum base 10A is not picked up (i.e., is absorbed/covered into/with black). As a result, the color tone by tame-nuri, which is composed of the below-described third step (primer coating) and fourth step (final coating), stands out more.

Returning to the description of the manufacturing process of the upper case 10 (case 1), in the third step, the urethane-based paint (vermilion) is applied (primer coating) to the surface of the aluminum oxide film 10B to form the first coating layer 10C made of the urethane-based paint (vermilion). This first coating layer 10C is then dried. In the third step, the urethane-based paint (vermilion) is applied (primer coating) to the surface of the aluminum oxide film 10B, thereby improving the adhesion between the aluminum oxide film 10B and the first coating layer 10C and between the first coating layer 10C and the below-described second coating layer 10D. In the fourth step, shuai urushi (of ki-urushi, i.e., raw lacquer) is applied (final coating) to the surface of the first coating layer 10C to form the second coating layer 10D made of shuai urushi. This second coating layer 10D is then dried until cured. The upper case 10 (case 1) is thus completed (manufactured).

In the fourth step, shuai urushi is applied in the state in which the top surface (flat surface) of the upper case 10 to be manufactured faces upward, i.e., the back surface thereof faces downward (direction of gravity). After the application, in the same state, the second coating layer 10D is dried until shuai urushi thereof is cured. Due to the surface tension of shuai urushi, the second coating layer 10D, i.e., the coating of shuai urushi, becomes thinner and thinner from the point where the upper case 10 starts to bend on the top surface of the upper case 10 (e.g., where the R shape of the outer edge of the upper case 10 starts). Thus, at the outer edge of the upper case 10 and the edges of the openings 11, 12, 13, the coating of shuai urushi is thin, so that the color (vermilion) of the urethane-based paint of the first coating layer 10C, which is the underlayer, is visible through the second coating layer 10D, and accordingly the color tone by tame-nuri stands out.

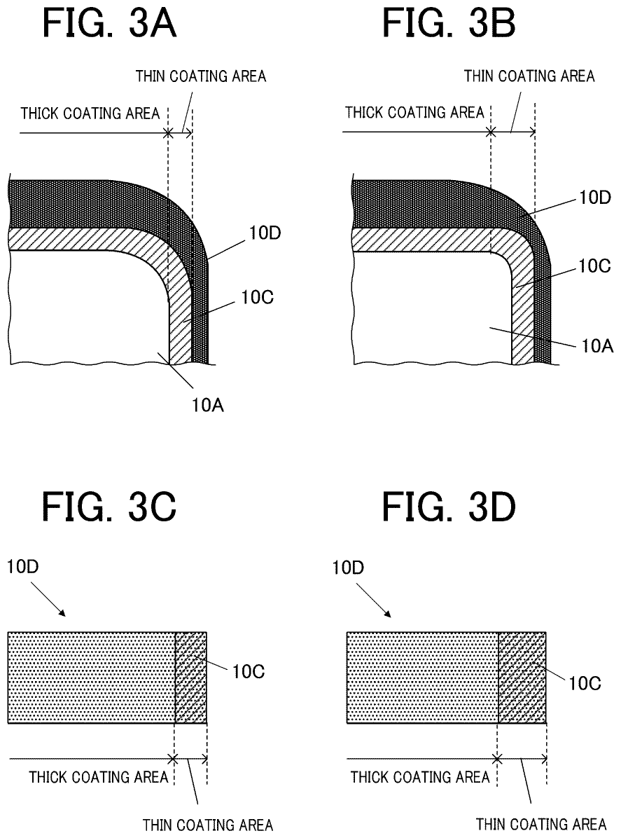

As shown in FIG. 3A to FIG. 3D, an area (thin coating area or second area) where the color (vermilion) of the urethane-based paint of the first coating layer 10C is visible can be adjusted by changing the size of the R shape of the curved surface part of the outer edge of the upper case 10. The same applies to the edges of the openings 11, 12, 13. FIG. 3A is a sectional view taken along a broken line in FIG. 2 viewed in a direction indicated by arrows A, A. FIG. 3B shows an example in which the size of the R shape in the sectional view of FIG. 3A is reduced (to be small). FIG. 3C and FIG. 3D show parts shown in FIG. 3A and FIG. 3B viewed from above the top surface of the upper case 10, respectively. As shown in FIG. 3A, in the case where the size of the R shape is large, the coating of shuai urushi becomes thinner and thinner from the point where the upper case 10 starts to bend. However, since the degree of thinning of the coating changes gradually, the proportion of the thick coating area where the coating of shuai urushi is thick (first area, i.e., area where the urethane-based paint of the first coating layer 10C is invisible through the second coating layer 10D) is large. That is, in the case where the size of the R shape is large, if the upper case 10 is viewed from above the top surface of the upper case 10, as shown in FIG. 3C, the proportion of the thin coating area to the second coating layer 10D is smaller than in the case where the size of the R shape is small (shown in FIG. 3D). Accordingly, the area (line width) of the urethane-based paint of the first coating layer 10C visible through the second coating layer 10D is smaller than in the case where the size of the R shape is small. On the other hand, as shown in FIG. 3B, in the case where the size of the R shape is small, the degree of thinning of the coating of shuai urushi changes sharply from the point where the upper case 10 starts to bend, so that the proportion of the thick coating area is smaller than in the case where the size of the R shape is large. That is, in the case where the size of the R shape is small, if the upper case 10 is viewed from above the top surface of the upper case 10, as shown in FIG. 3D, the proportion of the thin coating area to the second coating layer 10D is larger than in the case where the size of the R shape is large. Accordingly, the area (line width) of the urethane-based paint of the first coating layer 10C visible through the second coating layer 10D is larger than in the case where the size of the R shape is large. It may be an idea that while the outer edge of the upper case 10 is formed to have the R shape, the edges of the openings 11 into which the keys of the input key unit 2 are to be inserted are designed to be substantially vertical, i.e., designed such that the size of the R shape of the edges of the openings 11 is smaller than the size of the R shape of the outer edge of the upper case 10. In this case, the area (line width) of the urethane-based paint of the first coating layer 10C visible through the second coating layer 10D at the edge of each opening 11 is large, so that the color tone by tame-nuri stands out even in the state in which the keys of the input key unit 2 are inserted in the openings 11. Although not shown in FIG. 3A and FIG. 3B, the aluminum oxide film 10B is provided on the aluminum base 10A.

The conventional electrical product disclosed in JP 2005-229080 A has problems, for example, that weak adhesion between the surface of a case and a coating causes the coating to peel off easily and mars the beauty of the product.

In contrast, the calculator 100 of this embodiment has been made in view of the above circumstances, and objects of the present disclosure include providing an electronic device and a case the coating(s) of which hardly peels off and that are highly aesthetic. The calculator 100 (electronic device) 100 of this embodiment includes the case 1 including a coating layer(s) on the surface of the base material (aluminum material). The coating layer includes the first coating layer 10C that is provided on the base material (aluminum material) and the second coating layer 10D that includes raw lacquer (e.g., shuai urushi) and is provided on the first coating layer 10C. The first coating layer 10C is configured to improve the adhesion between the base material and the first coating layer 10C and between the first coating layer 10C and the second coating layer 10D. The second coating layer 10D has the thick coating area (first area) and the thin coating area (second area) where the second coating layer 10D is thinner than in the thick coating area. The second coating layer 10D is configured such that the paint color of the first coating layer 10C is visible through the second coating layer 10D in the thin coating area. According to the case 1 of the calculator 100, the first coating layer 10C is provided to improve the adhesion between the base material and the first coating layer 10C and between the first coating layer 10C and the second coating layer 10D, so that the first coating layer 10C and the second coating layer 10D hardly peel off. Further, according to the case 1 of the calculator 100, the second coating layer 10D has the thick coating area and the thin coating area where the second coating layer 10D is thinner than in the thick coating area, so that the color tone by tame-nuri, by which the paint color of the first coating layer 10 is visible though the second coating layer 10 in the thin coating area, stand out, and accordingly the beauty is enhanced.

Further, in the calculator 100 of this embodiment, the second coating layer 10D is configured such that the paint color of the first coating layer 10C is invisible through the second coating layer 10D in the thick coating area. According to the case 1 of the calculator 100, a contrast is present between the thick coating area and the thin coating area, so that the color tone by tame-nuri stands out more.

Further, in the calculator 100 of this embodiment, the base material of the case 1 is an anodized aluminum material. According to the case 1 of the calculator 100, the base material (aluminum base 10A) is anodized (aluminum oxide film 10B), so that the corrosion resistance and the abrasion resistance of the case 1 are improved. Since the base material (aluminum base 10A) is anodized, according to the case 1 of the calculator 100, the adhesion to the first coating layer 10C is also improved. Further, according to the case 1 of the calculator 100, the base material (aluminum base 10A) is anodized, and the black dye is used to make the surface on which the anodization (alumite treatment) has been performed black, so that the color (silvery white) of the base material (aluminum base 10A) is not picked up. As a result, the color tone by tame-nuri, the color tone being made by the first coating layer 10C and the second coating layer 10D, stands out even more.

Further, in the calculator 100 of this embodiment, the first coating layer 10C of the case 1 includes the urethane-based paint. According to the case 1 of the calculator 100, the first coating layer 10C is made of the urethane-based paint, so that the adhesion between the base material and the first coating layer 10C and between the first coating layer 10C and the second coating layer 10D is improved more.

Further, in the calculator 100 of this embodiment, shuai urushi is used as the raw lacquer. According to the case 1 of the calculator 100, the second coating layer 10D is less transparent and blackish at the onset of its being formed, but as time passes, the color (vermilion) of the urethane-based paint of the underlayer (first coating layer 10C) gradually becomes visible through the second coating layer 10D. Thus, change in color tone is achieved.

Further, in the calculator 100 of this embodiment, the thin coating area constitutes the outer edge of the case 1 due to the surface tension of the raw lacquer (shuai urushi), and the thick coating area constitutes the area of the case 1 excluding the outer edge. According to the case 1 of the calculator 100, the color tone of the first coating layer 10C appears at the outer edge of the case 1, so that the color tone by tame-nuri stands out, and accordingly the beauty is enhanced more.

Further, in the calculator 100 of this embodiment, the case 1 has the openings 11, 12, 13 (shown in FIG. 2). The thin coating area constitutes the edges of the openings 11, 12, 13, and the thick coating area constitutes the boundaries between the openings 11, 12, 13. According to the case 1 of the calculator 100, the color tone of the first coating layer 10C appears at the edges of the openings 11, 12, 13, so that the color tone by tame-nuri stands out even more, and accordingly the beauty is enhanced even more.

Although the present disclosure has been described in detail on the basis of the above embodiment, the present disclosure is not limited thereto but can be modified without departing from the scope of the present disclosure. For example, although in the above embodiment, the case 1 has the openings 11, 12, 13, the case 1 may have one opening or may not have any opening.

Further, although in the above embodiment, the anodized aluminum material is used as the base material of the case 1, another metal material may be used as the base material. If another metal material is used as the base material, the alumite treatment is unnecessary. Alternatively, wood may be used as the base material of the case 1. If wood is used as the base material, for example, Wajima-nuri may be performed in place of tame-nuri (third step and fourth step) described above.

Further, although in the third step (shown in FIG. 2) of the manufacturing process in the above embodiment, the urethane-based paint (vermilion) is applied (primer coating) to the surface of the aluminum oxide film 10B, the paint used for primer coating is not limited to the urethane-based paint. Any paint can be used as the paint for primer coating as far as it can ensure the adhesion described above. Further, although in the third step (shown in FIG. 2) of the manufacturing process in the above embodiment, the vermilion urethane-based paint is used as the paint for primer coating, the color of the urethane-based paint is not limited thereto. The color of the urethane-based paint may be blue, yellow, green or another color. In accordance with the color of the urethane-based paint, the color of the dye used for the alumite treatment (color alumite treatment) may not be black but another color. Further, the alumite treatment may not include coloring.

It is a matter of course that the detailed configuration of each component of the calculator 100 of the above embodiment can be changed as appropriate without departing from the scope of the present disclosure.

1. An electronic device comprising a case including a coating layer on a surface of a base material,
wherein the coating layer includes a first coating layer that is provided on the base material and a second coating layer that includes a raw lacquer and is provided on the first coating layer,
wherein the first coating layer is configured to improve adhesion between the base material and the first coating layer and between the first coating layer and the second coating layer, and
wherein the second coating layer has a first area and a second area where the second coating layer is thinner than in the first area, and is configured such that a paint color of the first coating layer is visible through the second coating layer in the second area.

2. The electronic device according to claim 1, wherein the second coating layer is configured such that the paint color of the first coating layer is invisible through the second coating layer in the first area.

3. The electronic device according to claim 1, wherein the base material is an anodized aluminum material.

4. The electronic device according to claim 1, wherein the first coating layer includes a urethane-based paint.

5. The electronic device according to claim 1, wherein the raw lacquer is shuai urushi.

6. The electronic device according to claim 1, wherein the second area constitutes an outer edge of the case due to a surface tension of the raw lacquer, and the first area constitutes an area of the case excluding the outer edge.

7. The electronic device according to claim 1,
wherein the case has an opening, and
wherein the second area constitutes an edge of the opening due to a surface tension of the raw lacquer.

8. The electronic device according to claim 1,
wherein the case has openings, and
wherein the second area constitutes an edge of each of the openings due to a surface tension of the raw lacquer, and the first area constitutes a boundary between the openings.

9. A case comprising a coating layer on a surface of a base material,
wherein the coating layer includes a first coating layer that is provided on the base material and a second coating layer that includes a raw lacquer and is provided on the first coating layer,
wherein the first coating layer is configured to improve adhesion between the base material and the first coating layer and between the first coating layer and the second coating layer, and
wherein the second coating layer has a first area and a second area where the second coating layer is thinner than in the first area, and is configured such that a paint color of the first coating layer is visible through the second coating layer in the second area.
